(19) United States
(12) Patent Application Publication
(10) Pub. No.: US 2016/0011247 A1
(43) Pub. Date: Jan. 14, 2016

(54) METERING CIRCUIT APPARATUS AND METHOD FOR IMPLEMENTING METERING

(71) Applicants: STATE GRID CORPORATION OF CHINA, Beijing (CN); STATE GRID BEIJING ELECTR POWER COMPANY, Beijing (CN); BEIJING ELECTRIC POWER ECONOMIC RESEARCH INSTITUTE, Beijing (CN)

(72) Inventors: Ranjing Yang, Beijing (CN); Manyuan Liu, Xicheng District Beijing (CN); Xiaohui Bai, Xicheng District Beijing (CN); Xiulan Yang, Xicheng District Beijing (CN); Wenbo Jin, Xicheng District Beijing (CN); Nan Gao, Xicheng District Beijing (CN); Fan Yang, Xicheng District Beijing (CN); Bing Qin, Xicheng District Beijing (CN); Tong Zhou, Xicheng District Beijing (CN)

(21) Appl. No.: 14/443,328

(22) PCT Filed: Jul. 16, 2013
(86) PCT No.: PCT/CN2013/079465

§ 371 Date: Sep. 14, 2015

(30) Foreign Application Priority Data
Nov. 15, 2012 (CN) 201210461281.1

(51) Int. Cl. G01R 21/133; G01R 15/18

(52) U.S. Cl. CPC G01R 21/133; G01R 15/18

(57) ABSTRACT

A meter circuit apparatus and a method for implementing metering are disclosed, wherein the apparatus includes: an electric energy meter (1), a combining unit (2) and a current transformer (3), wherein the current transformer (3) is connected to the combining unit (2) and the electric energy meter (1) and is configured to acquire an electrical quantity of a intelligent substation, and input the electrical quantity to the combining unit (2) and the electric energy meter (1); the combining unit (2) configured to combine and synchronize the electrical quantity inputted by the current transformer (3), and forward a processed digital signal in a specific format; and the electric energy meter (1) is configured to charge for the electrical quantity inputted by the current transformer (3). Requirements of regular metering and intelligent measurement are satisfied within adding an independent current transformer (3).

### TECHNICAL FIELD OF THE DISCLOSURE

The present disclosure relates to the electrical field, and particularly to a metering circuit apparatus and a method for implementing metering.

### BACKGROUND OF THE DISCLOSURE

At present, current and voltage analog quantities of an intelligent electric energy meter of an intelligent substation are acquired through connecting an optical cable of a combining unit to an electric meter. However, the traceability of a gateway electric energy meter is not certified by a national standard department, thus the gateway electric energy meter can not be used as a property settlement point and cannot be put into use in an intelligent substation.

In a related technology, an intelligent substation is assorted with a set of special 0.2S metering current transformer and a cable is connected to a junction box and a regular gateway electric energy meter to satisfy metering requirements while being assorted with a set of 0.2S (or 0.5S) measuring current transformer to connect a combining unit so as to satisfy measurement requirements of the intelligent substation.

FIG. 1 is a schematic diagram of a method for configuring a current transformer according to a related technology. As shown in FIG. 1, a set of metering current transformer is applied to metering of a current and a set of measuring current transformer is applied to measurement in the configuration method. FIG. 2 is a schematic diagram of a measuring circuit according to a related technology. As shown in FIG. 2, a measuring current transformer is connected to an 110 kV circuit combining unit. FIG. 3 is a schematic diagram of a metering circuit according to a related technology. As shown in FIG. 3, a metering current transformer is connected to a junction box, and an electric energy meter is connected to perform metering.

To sum up, at least two set of current transformers are needed to satisfy requirements of measurement of an intelligent substation, and metering of a gateway in the prior art, thus resulting in a complicated metering circuit and relatively high cost.

### SUMMARY OF THE DISCLOSURE

The present disclosure aims at providing a metering circuit apparatus and a method for implementing metering, so as to solve problems of a complicated metering circuit and relatively high cost in the prior art.

To achieve the purpose above, a metering circuit apparatus is provided according to an aspect of the present disclosure, including: an electric energy meter, a combining unit and a current transformer, wherein the current transformer is connected to the combining unit and the electric energy meter and is configured to acquire an electrical quantity of an intelligent substation and input the electrical quantity to the combining unit and the electric energy meter; the combining unit is configured to combine and synchronize the electrical quantity inputted by the current transformer, and forward a processed digital signal in a specific format; the electric energy meter is configured to charge for the electrical quantity inputted by the current transformer.

Further, the apparatus further includes: a junction box, configured to connect the current transformer to the combining unit.

Further, the junction box is further configured to connect the current transformer to the electric energy meter.

Further, the current transformer connects electric energy meter to the combining unit in series through the junction box by applying a secondary junction method.

Further, the current transformer is a 0.2S current transformer for metering.

A method for implementing metering is provided according to another aspect of the present disclosure, including that a current transformer acquires an electrical quantity of an intelligent substation and inputs the electrical quantity to a combining unit and an electric energy meter; the combining unit combines and synchronizes the electrical quantity inputted by the current transformer, and forwards a processed digital signal in a specific format; the electric energy meter charges for the electrical quantity inputted by the current transformer.

Further, inputting the electrical quantity into the combining unit and the electric energy meter includes that the current transformer inputs the electrical quantity into the combining unit and the electric energy meter through a junction box.

Further, the current transformer is a 0.2S current transformer for metering.

Applying a technical solution of the present disclosure, a current transformer is connected to a combining unit and an electric energy meter simultaneously, thus satisfying requirements of regular metering and an intelligent measurement method simultaneously without adding an independent current transformer, simplifying a metering circuit, and lowering the cost of the metering circuit.

### BRIEF DESCRIPTION OF THE DRAWINGS

The accompanying drawings of the specification, which constitute a part of the present application, are used for providing further understanding to present disclosure. The exemplary embodiments of the present disclosure and the illustration thereof are used for explaining the present disclosure instead of constituting an improper limitation to the present disclosure. In the accompanying drawings:

FIG. 1 is a schematic diagram of a method for configuring a current transformer according to a related technology;

FIG. 2 is a schematic diagram of a measuring circuit according to a related technology;

FIG. 3 is a schematic diagram of a metering circuit according to a related technology;

FIG. 4 is a schematic diagram of a metering circuit apparatus according to an embodiment of the present disclosure;

FIG. 5 is a structure block diagram of a metering circuit apparatus according to an embodiment of the present disclosure; and

FIG. 6 is a flowchart of a method for implementing metering according to an embodiment of the present disclosure.

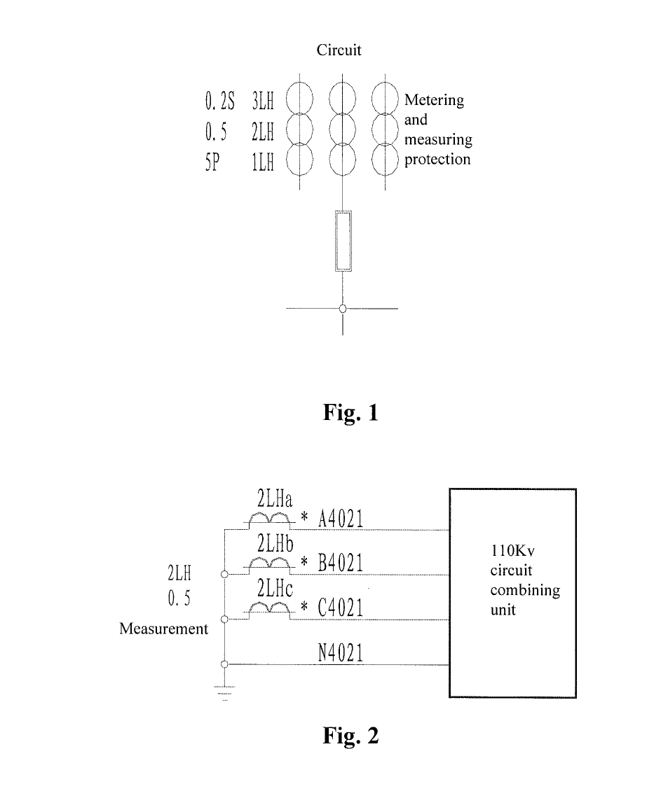

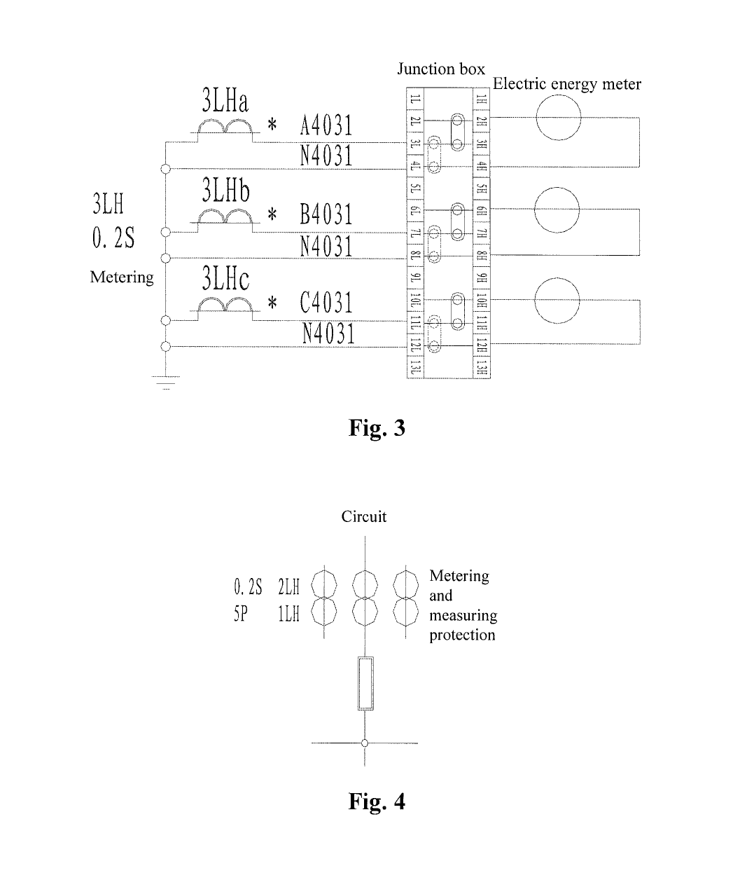

### DETAILED DESCRIPTION OF THE EMBODIMENTS

Notably, the embodiments in the application and the characteristics in the embodiments may be combined with each other if there is no conflict. The present disclosure will be expounded below with reference to the accompanying drawings and in conjunction with the embodiments.

A metering circuit apparatus is provided according to an embodiment of the present disclosure, and a set of current transformer is applied to satisfying requirements of regular metering and an intelligent measurement method simultaneously.

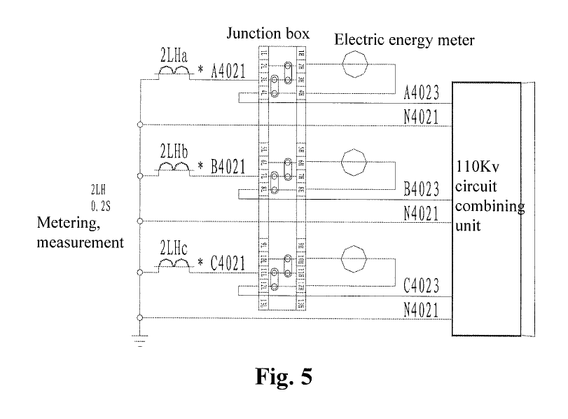

FIG. 4 is a schematic diagram of a metering circuit apparatus according to an embodiment of the present disclosure. As shown in FIG. 4, the device only includes a set of current transformer. A structure of a metering circuit apparatus according to an embodiment of the present disclosure will be described in combination with FIG. 5.

FIG. 5 is a structure block diagram of a metering circuit apparatus according to an embodiment of the present disclosure. As shown in FIG. 5, the metering circuit apparatus mainly includes: an electric energy meter, a combining unit and a current transformer, wherein the current transformer is connected to the combining unit and the electric energy meter and is configured to acquire an electrical quantity of an intelligent substation and input the electrical quantity to the combining unit and the electric energy meter; the combining unit is configured to combine and synchronize the electrical quantity inputted by the current transformer, and forward a processed digital signal in a specific format; the electric energy meter is configured to charge for the electrical quantity inputted by the current transformer.

In an embodiment of the present disclosure, the metering circuit apparatus may further include: a junction box configured to connect the current transformer to the combining unit. Further, the junction box is further configured to connect the current transformer to the electric energy meter.

Further, in an embodiment of the present disclosure, the current transformer connects electric energy meter to the combining unit in series through the junction box by applying a secondary junction method, and specific circuit connection is as shown in FIG. 5.

In an embodiment of the present disclosure, the current transformer is a 0.2S current transformer for metering, thus satisfying requirements of measurement and metering simultaneously.

By applying a technical solution of an embodiment of the present disclosure, an electric energy meter and a junction box are connected to a combining unit in series without adding an independent metering current transformer, thus satisfying requirements of regular metering and an intelligent measurement method simultaneously.

A method for implementing metering is further provided according to an embodiment of the present disclosure. The method applies a set of current transformer to satisfy requirements of metering and measurement simultaneously.

Notably, a method for implementing metering of an embodiment of the present disclosure may be implemented by a metering circuit apparatus of an embodiment of the present disclosure. A metering circuit apparatus of an embodiment of the present disclosure may be also applied to implementing a method for implementing metering of an embodiment of the present disclosure.

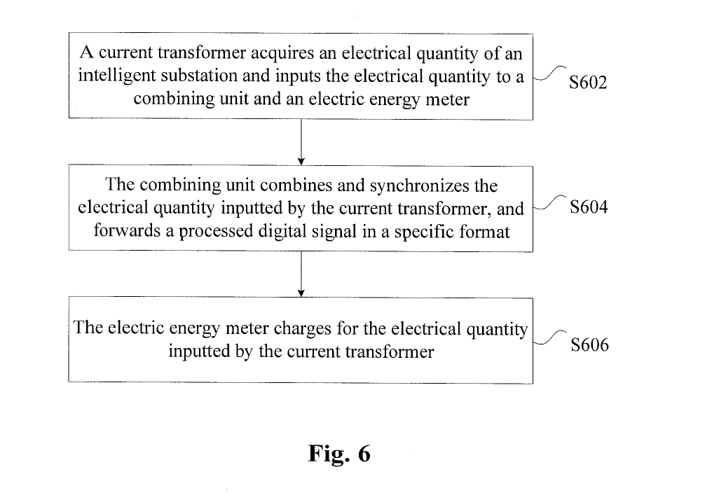

FIG. 6 is a flowchart of a method for implementing metering according to an embodiment of the present disclosure. As shown in FIG. 6, the method mainly includes Step 602 to Step 606.

Step 602: A current transformer acquires an electrical quantity of an intelligent substation and inputs the electrical quantity to a combining unit and an electric energy meter.

Step 604: The combining unit combines and synchronizes the electrical quantity inputted by the current transformer, and forwards a processed digital signal in a specific format.

Step 606: The electric energy meter charges for the electrical quantity inputted by the current transformer.

Further, the current transformer inputs a converted current into the electric energy meter and the combining unit, including that the current transformer inputs the electrical quantity into the combining unit and the electric energy meter through a junction box.

Further, the current transformer is a 0.2S current transformer for metering, thus satisfying requirements of measurement and metering simultaneously.

By applying a technical solution of the present disclosure, a current transformer inputs, after converting the current of an intelligent substation, the current into a combining unit and an electric current meter simultaneously, thus satisfying requirements of regular metering and an intelligent measurement method simultaneously without adding an independent current transformer, simplifying a metering circuit, and lowering the cost of the metering circuit.

It may be learned from the description above that the embodiments of the present disclosure implement the following technical effect: an electric energy meter and a junction box are connected to a combining unit in series without adding an independent metering current transformer, thus satisfying requirements of regular metering and an intelligent measurement method simultaneously.

The foregoing descriptions are only preferred embodiments of the present invention and are not used for limiting the present invention. For those skilled in the art, the present invention may have various alternations and changes. All modifications, equivalent replacements and improvements and the like made within the spirit and principle of the present invention shall be included within the protection scope of the present invention.

1. A metering circuit apparatus, comprising: an electric energy meter, a combining unit and a current transformer, wherein
the current transformer is connected to the combining unit and the electric energy meter and is configured to acquire an electrical quantity of an intelligent substation and input the electrical quantity to the combining unit and the electric energy meter;
the combining unit is configured to combine and synchronize the electrical quantity inputted by the current transformer, and forward a processed digital signal in a specific format;
the electric energy meter is configured to charge for the electrical quantity inputted by the current transformer.

2. The apparatus according to claim 1, further comprising:
a junction box, configured to connect the current transformer to the combining unit.

3. The apparatus according to claim 2, wherein
the junction box is further configured to connect the current transformer to the electric energy meter.

4. The apparatus according to claim 3, wherein the current transformer connects electric energy meter to the combining unit in series through the junction box by applying a secondary junction method.

5. The apparatus according to claim 1, wherein the current transformer is a 0.2S current transformer for metering.

6. A method for implementing metering, comprising:
acquiring, by a current transformer, an electrical quantity of an intelligent substation and inputting, by the current transformer, the electrical quantity to a combining unit and an electric energy meter;
combining and synchronizing, by the combining unit, the electrical quantity inputted by the current transformer, and forwarding, by the combining unit, a processed digital signal in a specific format;
charging, by the electric energy meter, for the electrical quantity inputted by the current transformer.

7. The method according to claim 6, wherein inputting the electrical quantity into the combining unit and the electric energy meter includes:
inputting, by the current transformer, the electrical quantity into the combining unit and the electric energy meter through a junction box.

8. The method according to claim 6, wherein the current transformer is a 0.2S current transformer for metering.
